(19) United States
(12) Patent Application Publication
(10) Pub. No.: US 2013/0020599 A1
(43) Pub. Date: Jan. 24, 2013

(54) SEMICONDUCTOR LIGHT EMITTING DEVICE

(71) Applicants: Jae Ho HAN, Hwaseong (KR); Je Won KIM, Seoul (KR); Hae Soo HA, Hwaseong (KR)

(72) Inventors: Jae Ho HAN, Hwaseong (KR); Je Won KIM, Seoul (KR); Hae Soo HA, Hwaseong (KR)

(73) Assignee: SAMSUNG ELECTRONICS CO., LTD.

(21) Appl. No.: 13/554,508

(22) Filed: Jul. 20, 2012

(30) Foreign Application Priority Data
Jul. 22, 2011 (KR) 10-2011-0073161

(51) Int. Cl. H01L 33/00

(52) U.S. Cl. 257/98; 257/E33.06

(57) ABSTRACT

A semiconductor light emitting device is provided. The semiconductor light emitting device includes a light emitting structure including a first conductivity-type semiconductor layer, an active layer, and a second conductivity-type semiconductor layer. A first electrode is electrically connected to the first conductivity-type semiconductor layer. A light-transmissive conductive layer is disposed on the second conductivity-type semiconductor layer. A second electrode includes a reflective metal layer and an insulating layer.

### CROSS-REFERENCE TO RELATED APPLICATIONS

This application claims priority to Korean Patent Application No. 10-2011-0073161, filed on Jul. 22, 2011, in the Korean Intellectual Property Office, the disclosure of which is incorporated herein by reference.

### TECHNICAL FIELD

The present application relates to a semiconductor light emitting device.

### BACKGROUND

In general, a nitride semiconductor material has been widely used in a green or blue light emitting diode (LED) or in a laser diode provided as a light source in a full-color display, an image scanner, various signaling systems, or in an optical communications device. A nitride semiconductor light emitting device may be provided as a light emitting device having an active layer emitting light of various colors, including blue and green, through the recombination of electrons and holes.

As remarkable progress has been made in the area of nitride semiconductor light emitting devices since they were first developed, the utilization thereof has been greatly expanded and research into utilizing semiconductor light emitting devices as light sources of general illumination devices and electronic devices, has been actively undertaken. In particular, related art nitride light emitting devices have largely been used as components of low-current/low-output mobile products, and recently, the utilization of nitride light emitting devices has extended into the field of high-current/high-output devices. Thus, research into improving luminance efficiency and the quality of semiconductor light emitting devices has been actively undertaken.

However, there is still room for improvement, for example, in terms of quality, luminance efficiency, external light extraction efficiency and optical power of the semiconductor light emitting device.

### SUMMARY

The teachings herein provide further improvements over existing technology by providing a semiconductor light emitting device with improved quality, increased luminance efficiency, and improved external light extraction efficiency and optical power.

An exemplary semiconductor light emitting device includes a light emitting structure including a first conductivity-type semiconductor layer, an active layer, and a second conductivity-type semiconductor layer. A first electrode is formed to be electrically connected to the first conductivity-type semiconductor layer. A light-transmissive conductive layer is disposed on the second conductivity-type semiconductor layer and has an open region exposing a portion of the second conductivity-type semiconductor layer. A second electrode includes a reflective metal layer disposed on the second conductivity-type semiconductor layer exposed through the open region. An insulating layer is interposed between the light-transmissive conductive layer and the reflective metal layer. An electrode pad is disposed on the reflective metal layer. A branch electrode extends from the electrode pad so as to be in contact with the light-transmissive conductive layer.

In certain examples, the insulating layer extends from a lateral surface of the reflective metal layer so as to be interposed between the second conductivity-type semiconductor layer and the reflective metal layer.

In other examples, the reflective metal layer is formed to have an area equal to or smaller than that of the electrode pad on the second conductivity-type semiconductor layer.

The electrode pad may be formed to cover the entire surface of the reflective metal layer such that the reflective metal layer is not exposed to the outside.

The reflective metal layer may be formed to fill the open region.

The insulating layer may be formed to cover a surface of the light-transmissive conductive layer exposed from the inner side of the open region.

In yet other examples, the semiconductor light emitting device includes a current interrupting layer interposed between the reflective metal layer and the second conductivity-type semiconductor layer.

The current interrupting layer may be disposed on a region corresponding to the electrode pad formation region.

The current interrupting layer may be made of an undoped semiconductor or an insulating material.

The reflective metal layer and the electrode pad may include the same metal.

The reflective metal layer may include at least one of silver (Ag), nickel (Ni), aluminum (Al), rhodium (Rh), ruthenium (Ru), palladium (Pd), iridium (Ir), magnesium (Mg), zinc (Zn), platinum (Pt), and gold (Au).

The electrode pad may be comprised of any one of Ni/Au, Ag/Au, Ti/Au, Ti/Al, Cr/Au, Pd, and Au.

Other examples include a surface of the light emitting structure, on which the second electrode is formed, provided as a main light emission surface of the semiconductor light emitting device.

In another example, a semiconductor light emitting device includes a light emitting structure disposed on a substrate. The light emitting structure includes a first conductivity-type semiconductor layer, an active layer, and a second conductivity-type semiconductor layer. A first electrode is electrically connected to the first conductivity-type semiconductor layer. A light-transmissive conductive layer is disposed on the second conductivity-type semiconductor layer. A second electrode is disposed on the light-transmissive conductive layer. The second electrode includes a reflective metal layer including a portion disposed on the second conductivity-type semiconductor layer. An insulating layer is interposed between the light-transmissive conductive layer and the reflective metal layer.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1 is a perspective view schematically showing an exemplary semiconductor light emitting device;

FIG. 2 is a schematic cross-sectional view of the semiconductor light emitting device according to the example illustrated in FIG. 1 taken along line A-A′;

FIG. 3 is a cross-sectional view schematically showing a second electrode according to another example;

FIG. 4 is a cross-sectional view schematically showing a second electrode according to another example;

FIG. 5 is a cross-sectional view schematically showing a second electrode according to another example;

FIGS. 6A and 6B are views showing electrode structures according to an example of the present application and a comparative example, and a corresponding power map, respectively; and

FIG. 7 is a graph showing a comparison between optical powers of the comparative example and an example of the present application.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

Examples of the present application will now be described in detail with reference to the accompanying drawings. In the drawings, the shapes and dimensions of elements may be exaggerated for clarity.

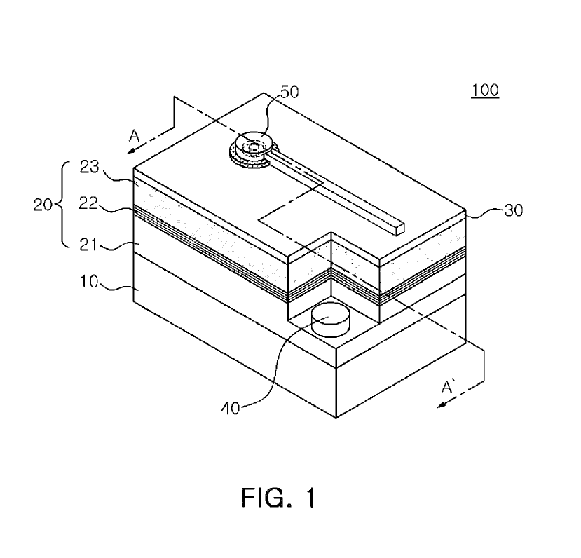

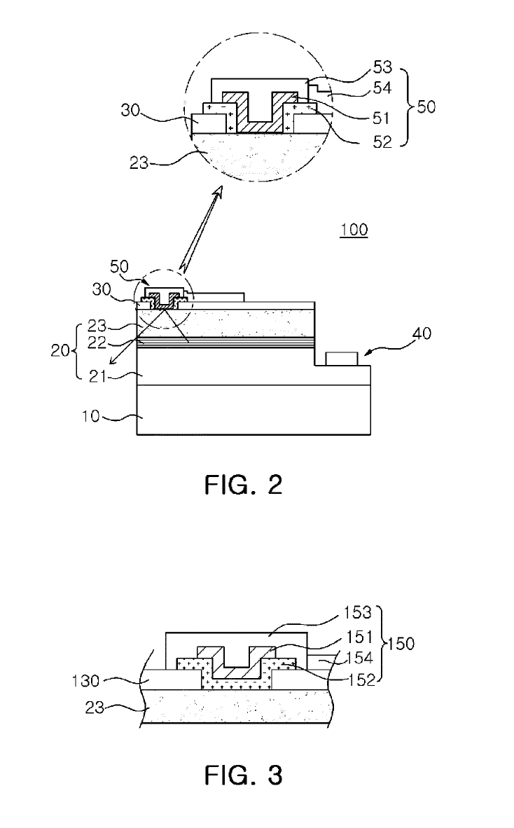

FIG. 1 is a perspective view schematically showing a semiconductor light emitting device and FIG. 2 is a schematic cross-sectional view of the semiconductor light emitting device according to the example illustrated in FIG. 1 taken along line A-A′.

With reference to FIGS. 1 and 2, semiconductor light emitting device 100 includes a light emitting structure 20 including a first conductivity-type semiconductor layer 21, an active layer 22, and a second conductivity-type semiconductor layer 23 disposed on a substrate 10. A first electrode 40 is formed to be electrically connected to the first conductivity-type semiconductor layer 21. A light-transmissive conductive layer 30 is disposed on the second conductivity-type semiconductor layer 23 and has an open region exposing a portion of the second conductivity-type semiconductor layer 23 A second electrode 50 is electrically connected to the second conductivity-type semiconductor layer 23. As shown in the enlarged view of FIG. 2, the second electrode 50 includes a reflective metal layer 51 disposed on the second conductivity-type semiconductor layer 23 exposed through the open region. A portion of the reflective metal layer is disposed on the second conductivity-type semiconductor layer 23. An insulating layer 52 is interposed between the light-transmissive conductive layer 30 and the reflective metal layer 51. An electrode pad 53 is disposed on the reflective metal layer 51, and a branch electrode 54 extends from the electrode pad 53 so as to come into contact with the light-transmissive conductive layer 30.

For the example in FIG. 1, the first and second conductivity-type semiconductor layers 21 and 23 may be n-type and p-type semiconductor layers, respectively, and may be made of a nitride semiconductor. Thus, in this example, the first and second conductivity-types may be understood to indicate n-type and p-type conductivities, respectively, but not limited thereto. The first and second conductivity-type semiconductor layers 21 and 23 may be made of a material expressed by an empirical formula AlₓIn_{y}Ga(_{1-x-y})N (here, 0≦x≦1, 0≦y≦1, 0≦x+y≦1), and such a material may include GaN, AlGaN, InGaN, and the like. The active layer formed between the first and second conductivity-type semiconductor layers 21 and 23 emits light having a certain level of energy according to electron and hole recombination, and may have a multi-quantum well (MQW) structure in which quantum well layers and quantum barrier layers are alternately laminated. Here, the MQW structure may be, for example, an InGaN/GaN structure. Meanwhile, the first and second conductivity-type semiconductor layers 21 and 23 and the active layer 22 may be formed by using a conventional semiconductor layer growth process such as metal organic chemical vapor deposition (MOCVD), hydride vapor phase epitaxy (HVPE), molecular beam epitaxy (MBE), or the like.

The light emitting structure 20 may be disposed on a substrate 10 such as a semiconductor growth substrate. The semiconductor growth substrate 10 can be made of a material such as sapphire, SiC, MgAl₂O₄, MgO, LiAlO₂, LiGaO₂, GaN, or the like. In certain examples, the sapphire substrate is a crystal having Hexa-Rhombo R3c symmetry, of which lattice constants in c-axis and a-axis directions are 13.001 Å and 4.758 Å, respectively. The sapphire crystal has a C plane (0001), an A plane (1120), an R plane (1102), and the like. In this case, a nitride thin film may be relatively easily disposed on the C plane of the sapphire crystal and because sapphire crystal is stable at high temperatures. Sapphire crystal is known in the art as a material for a nitride growth substrate. A buffer layer (not shown) may be employed as an undoped semiconductor layer made of a nitride, or the like, to alleviate a lattice defect in the semiconductor layer grown thereon.

As shown in FIG. 1, first and second electrodes 40 and 50 are disposed on the first and second conductivity-type semiconductor layers 21 and 22 and electrically connected to the second conductivity-type semiconductor layers 21 and 22, respectively. As further illustrated in FIG. 1, the first electrode 40 is disposed on the first conductivity-type semiconductor layer 21 exposed as portions of the second conductivity-type semiconductor layer 23, the active layer 22, and the first conductivity-type semiconductor layer 21 are etched, and the second electrode 50 is disposed on the second conductivity-type semiconductor layer 23.

In the example of the structure illustrated in FIGS. 1 and 2, the first and second conductivity-type electrodes 40 and 50 are formed to face in the same direction, but the position and connection structure of the first and second electrodes 40 and 50 may be variably modified as necessary. As an alternative example, a second electrode (not shown) may be disposed on the first conductivity-type semiconductor layer 21 exposed as the substrate 10 is removed, such that the first and second electrodes face in mutually opposite directions.

In the example of FIG. 1, the light-transmissive conductive layer 30 is disposed on the second conductivity-type semiconductor layer 23 of the light emitting structure 20 in order to enhance a current spreading effect. The light-transmissive conductive layer 30 may be made of a metal oxide such as indium tin oxide (ITO), ZnO, RuOₓ, TiOₓ, IrOₓ, or the like. The light-transmissive conductive layer 30 serves to increase a flow of an electric current in a horizontal direction in the light emitting structure 20. When a current is injected through the second electrode 50, the majority of the current flows in a vertical direction from the position at which the current is injected, causing a problem in which the current is concentrated on a portion of the interior of the device. In this case, however, when the light-transmissive conductive layer 30 is disposed on the second conductivity-type semiconductor layer 23, the current injected through the second electrode 50 is spread in the horizontal direction through the light-transmissive conductive layer so as to flow evenly through the entire device, thereby enhancing current spreading efficiency.

As shown in FIG. 2, the second electrode 50 is disposed on the second conductivity-type semiconductor layer 23 exposed as a portion of the light-transmissive conductive layer 30 is eliminated, and is electrically connected to the second conductivity-type semiconductor layer 23. The second electrode 50, as shown in FIG. 2, includes the reflective metal layer 51, the electrode pad 53 disposed on the reflective metal layer 51, the insulating layer 52 interposed between the light-transmissive conductive layer 30 and the reflective metal layer 51, and the branch electrode 54 extending from the electrode pad 53 so as to be in contact with the light-transmissive conductive layer 30. As further shown in FIG. 2, the reflective metal layer 51 reflects light emitted from the active layer 22 of the light emitting structure 20, reducing a proportion of light absorbed into the second electrode 50 to thus enhance external light extraction efficiency.

The reflective metal layer 51 may include a highly reflective metal, for example, silver (Ag), nickel (Ni), aluminum (Al), rhodium (Rh), ruthenium (Ru), palladium (Pd), iridium (Ir), magnesium (Mg), zinc (Zn), platinum (Pt), gold (Au), or the like, to have an advantage of light reflection. Also, the reflective metal layer 51 may have a structure including two or more layers to enhance reflecting efficiency. For example, the reflective metal layer 51 may have a structure of Ni/Ag, Zn/Ag, Ni/Al, Zn/Al, Pd/Ag, Pd/Al, Ir/Ag, Ir/Au, Pt/Ag, Pt/Al, Ni/Ag/Pt, or the like, but is not limited thereto. Indeed, various metals may be applied to the reflective metal layer 51 so long as they have a light reflection function/property.

If the reflective metal layer 51 is in contact with the light-transmissive conductive layer 30, a metal material of the reflective metal layer 51 and a material of the light-transmissive conductive layer 30 may react to degrade the function of the reflective metal layer 51 and the light-transmissive conductive layer 30, respectively. Thus, in an effort to solve this problem, if the reflective metal layer 51 and the light-transmissive conductive layer 30 are formed to be separated from each other to prevent contact therebetween, the area of the reflective metal layer 51 is reduced to be too small to sufficiently perform a light reflection function.

Thus, in the present example, the insulating layer 52 is formed between the light-transmissive conductive layer 30 and the reflective metal layer 51 to prevent the light-transmissive conductive layer 30 and the reflective metal layer 51 from coming into contact and reacting with each other. The area of the reflective metal layer 51 is maximized to allow the reflective metal layer 51 to effectively serve as a light reflecting layer. Here, an upper portion of the second conductivity-type semiconductor layer 23 may be provided as a main light emission surface, and the reflective metal layer 51 serves to reduce light absorbed under the electrode pad 53, so the formed reflective metal layer 51 is not required to be greater than the electrode pad 53. Thus, in this example, the reflective metal layer 51 is formed to have an area equal to or smaller than that of the electrode pad 53 on the second conductivity-type semiconductor layer 23.

The insulating layer 52 is interposed between the reflective metal layer 51 and the light-transmissive conductive layer 30, and covers a portion of the surface of the light-transmissive conductive layer 30. The insulating layer 52 may be made of any material having electrical insulation properties, and here, it is preferable for the insulating layer 52 to absorb as little light as possible, so, for example, a silicon oxide or a silicon nitride such as, for example, SiO₂, SiOₓN_{y}, SiₓN_{y}, or the like, may be used.

The electrode pad 53 serves to directly receive an electrical signal from the outside through a wire, or the like. Various metals may be used to form the electrode pad 53, and the electrode pad 53 may be a dual-layer structure in which, for example, Ni/Au, Ag/Au, Ti/Au, Pd, Au, Ti/Al, Cr/Au, or the like, are sequentially laminated. Here, the electrode pad 53 and the reflective metal layer 51 may be comprised of the same material or include the same material, and here in order to prevent the electrode pad 53 and the light-transmissive conductive layer 30 from being in contact and reacting with each other. The insulating layer 52 also separates the electrode pad 53 from the light-transmissive conductive layer 30. Also, in order to effectively receive an electrical signal from the outside, the electrode pad 53 may be formed to cover the entire surface of the reflective metal layer 51 such that the reflective metal layer 51 is not exposed to the outside.

In FIGS. 1 and 2, the branch electrode 54 extending from the electrode pad 53 of the second electrode 50 is disposed on the light-transmissive conductive layer 30. In FIGS. 1 and 2, a single branch electrode 54 is illustrated, but unlike the illustration of FIGS. 1 and 2, a plurality of branch electrodes 54 may be formed to allow a current injected through the electrode pad 53 to be evenly distributed throughout the entirety of the regions of the device. If a large area of the branch electrode 54 is in contact with the second conductivity-type semiconductor layer 23, the majority of the current injected to the branch electrode 54 flows vertically in a downward direction, making light emission concentrated in the vicinity of the branch electrode 54, so uniformity of light emissions may be degraded. In order to prevent this phenomenon, the insulating layer 52, in this example, extends to a portion of a region between the branch electrode 54 and the second conductivity-type semiconductor layer 23 to thereby reduce the area in which the branch electrode 54 and the second conductivity-type semiconductor layer 23 are in contact.

FIG. 3 is a cross-sectional view schematically showing another example of a second electrode. Second electrode 150 includes a reflective metal layer 151 disposed on the second conductivity-type semiconductor layer 23 exposed through an open region of a light-transmissive conductive layer 130. An insulating layer 152 is interposed between the light-transmissive conductive layer 130 and the reflective metal layer 151. An electrode pad 153 is disposed on the reflective metal layer 151, and a branch electrode 154 extends from the electrode pad 153 so as to be in contact with the light-transmissive reflective layer 130. Unlike the example illustrated in FIG. 2, in the example of FIG. 3, the insulating layer 152 extends from a lateral surface of the reflective metal layer 151 downwardly so as to be interposed between the second conductivity-type semiconductor layer 23 and the reflective metal layer 151, and the electrode pad 153 is formed to cover the surfaces of the insulating layer 152 and the reflective metal layer 151 and is in direct contact with the light-transmissive conductive layer 130.

In the example shown in FIG. 3, the insulating layer 152 that is formed beneath the reflective metal layer 151 may additionally serve to prevent a current injected through the electrode pad 153 from being concentrated on a lower region of the electrode pad 153. Namely, the insulating layer 152 separates the light-transmissive conductive layer 130 and the reflective metal layer 151 and prevents a current injected through the electrode pad 153 from being concentrated on the lower region thereof, thus enhancing current spreading efficiency. In addition, the electrode pad 153 is formed to be in direct contact with the light-transmissive conductive layer 130 to enhance current injection efficiency and heat dissipation efficiency.

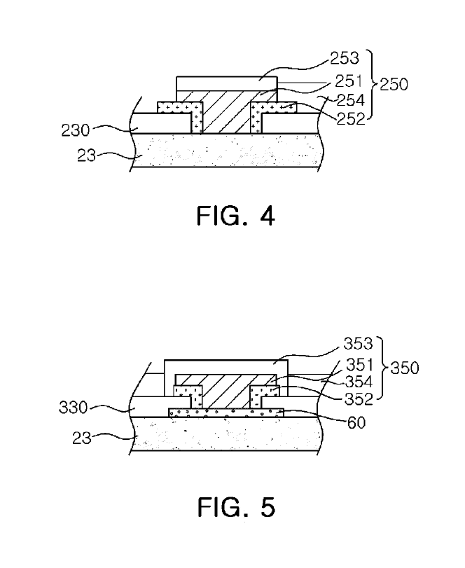

FIG. 4 is a cross-sectional view schematically showing another example of a second electrode. The second electrode 250 includes a reflective metal layer 251 disposed on the second conductivity-type semiconductor layer 23. An insulating layer 252 is interposed between the reflective metal layer 251 and a light-transmissive conductive layer 230. An electrode pad 253 is disposed on the reflective metal layer 251, and a branch electrode 254 is in contact with the light-transmissive conductive layer 230. The reflective metal layer 251 in FIG. 4 is formed to fill an open region formed as a portion of the light-transmissive conductive layer 230 is removed such that the second conductivity-type semiconductor layer 23 is exposed. Here, the insulating layer 252 is formed to cover a surface of the light-transmissive conductive layer 230 exposed from an inner side of the open region. Meanwhile, the electrode pad 253 is disposed on an upper surface of the reflective metal layer 251 so as to advantageously receive a current from the outside.

FIG. 4 demonstrates one of various shapes of the second electrode 250, and there is no limitation of a specific shape for the second electrode as long as the insulating layer 252 separates the light-transmissive conductive layer 230 and the reflective metal layer 251, such that they are not in contact. In addition, various other electrode structures may be employed as necessary. Also, although not shown, like the example illustrated in FIG. 3, the insulating layer 252 may be formed to extend to an upper surface of the second conductivity-type semiconductor layer 23 exposed as the light-transmissive conducive layer 230 is removed, namely, the open region, and in this case, current concentration on the region of the second conductivity-type semiconductor layer 23 in contact with the second electrode 250 can be prevented, to thereby enhance current spreading efficiency.

FIG. 5 is a cross-sectional view schematically showing yet another example of a second electrode. A current interrupting layer 60 is further interposed between the second electrode 350 including a reflective metal layer 351, an insulating layer 352, and an electrode pad 353 and the second conductivity-type semiconductor layer 23. The current interrupting layer 60, in this example, prevents current concentration in a current injection region, and is disposed on a region corresponding to the electrode pad 353. The current interrupting layer 60, serving to prevent current concentration, and is made of an insulating material or formed of an undoped semiconductor layer, or the like, and may include any one of, for example, SiO₂, Si₃N₄, TiO₂, HfO₂, Y₂O₃, MgO, and AlN.

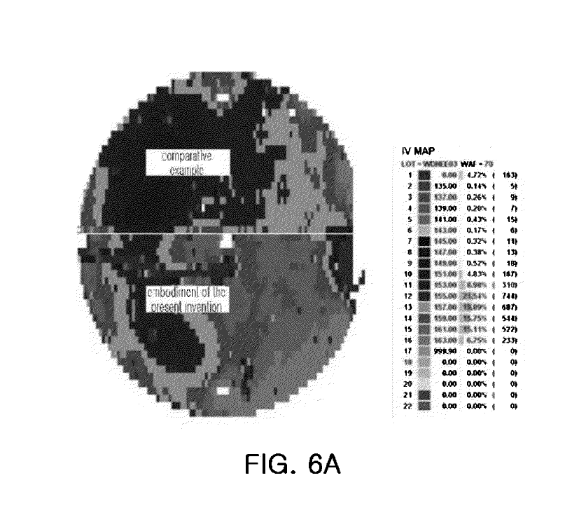

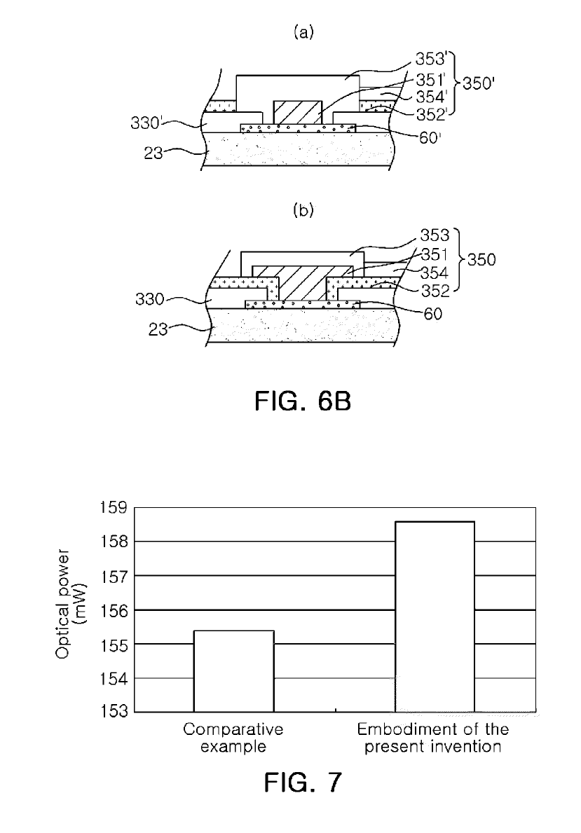

FIGS. 6A and 6B are views showing electrode structures according to an example of the present application and a comparative example, and a corresponding power map, respectively. Specifically, FIG. 6A shows a power map of the illustrated electrode structures illustrated in FIG. 6B, and the power map shows luminance on the surface of the electrodes, by colors corresponding to respective ranks 1 to 22.

FIG. 6B(a) shows a comparative example and FIG. 6B(b) shows an example of the present application. In detail, FIG. 6B(a) shows a structure in which a current interrupting layer 60′ and a light-transmissive conductive layer 330′ are disposed on a second conductivity-type semiconductor layer 23′. A reflective metal layer 351′ is formed to be spaced apart from the light-transmissive conductive layer 330′ such that the reflective metal layer 351′ is not in contact with the light-transmissive conductive layer 330′. An electrode pad 353′ is disposed on the reflective metal layer 351′, and a branch electrode 354′ extends from the electrode pad 353′.

FIG. 6B(b) shows the same configuration as that of the electrode structure illustrated in FIG. 5, in which the current interrupting layer 60 and the light-transmissive conductive layer 330 are disposed on the second conductivity-type semiconductor layer 23. The insulating layer 352 is interposed between the reflective metal layer 351 and the light-transmissive conductive layer 330 such that the reflective metal layer 351 and the light-transmissive conductive layer 330 are not in contact. The electrode pad 353 is disposed on the reflective metal layer 351, and the branch electrode 354 extends from the electrode pad 353.

In the comparative example and the example illustrated in FIGS. 6B(a) and 6B(b), respectively, the reflective metal layers 351 and 351′ were made of aluminum (Al), the electrode pads 353 and 353′ were formed of Cr/Au, the insulating layers 352 and 352′ were made of SiO₂, and the light-transmissive conductive layers 330 and 330′ were made of indium tin oxide (ITO). Also, ITO disposed on the second conductivity-type semiconductor layers 23 and 23′ was identical and the areas of the electrode pads 353 and 353′ were equal. However, in order to prevent ITO as the light-transmissive conductive layers 330 and 330′ from being in contact with the reflective metal layers 351 and 351′, in the comparative example, the area of the reflective metal layer 351′ is reduced (the area of the reflective metal layer 351′ is about 85% of the area of the electrode pad 353′), while, in the example of the present application, the insulating layer 352 was disposed on the surface of the light-transmissive conductive layer 330 and the reflective metal layer 351 was disposed on the upper surface of the insulating layer 352, thereby increasing the area of the reflective metal layer 351 (the area of the reflective metal layer 351 is about 97% of the area of the electrode pad 353′). With reference to FIG. 6A, it can be seen that the example of the present application, in which the area of the reflective metal layer was increased to be greater by about 13%, clearly exhibits luminance higher than that of the comparative example (luminance is increased as ranks 1 to 22 become higher in the power map of FIG. 6A).

FIG. 7 is a graph showing a comparison between optical powers of the comparative example and the an example of the present application. Specifically, FIG. 7 is a graph showing a comparison between optical powers of the semiconductor light emitting devices employing the electrode structures of the comparative example and the example illustrated in FIGS. 6B(a) and 6B(b).

With reference to FIG. 7, it can be seen that, when the area of the reflective metal layer 351 was increased to be 98% of that of the electrode pad 353 by interposing the insulating layer 352 between the light-transmissive conductive layer 350 and the reflective metal layer 351, the optical power was increased by about 3 mW, in comparison to the comparative example in which the area of the reflective metal layer 351′ was about 85% of that of the electrode pad 353′.

As set forth above, according to examples of the present application, the semiconductor light emitting device has enhanced external light extraction efficiency and optical power by maximizing the area of the reflective metal layer of the electrode pad.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A semiconductor light emitting device comprising:
a light emitting structure including:
a first conductivity-type semiconductor layer,
an active layer, and
a second conductivity-type semiconductor layer;
a first electrode electrically connected to the first conductivity-type semiconductor layer;
a light-transmissive conductive layer disposed on the second conductivity-type semiconductor layer, the light-transmissive conductive layer having an open region exposing a portion of the second conductivity-type semiconductor layer; and
a second electrode including:
a reflective metal layer disposed on the second conductivity-type semiconductor layer exposed through the open region,
an insulating layer interposed between the light-transmissive conductive layer and the reflective metal layer,
an electrode pad disposed on the reflective metal layer, and
a branch electrode extending from the electrode pad so as to be in contact with the light-transmissive conductive layer.

2. The semiconductor light emitting device of claim 1, wherein the insulating layer extends from a lateral surface of the reflective metal layer to be interposed between the second conductivity-type semiconductor layer and the reflective metal layer.

3. The semiconductor light emitting device of claim 1, wherein the reflective metal layer has an area equal to or smaller than that of the electrode pad on the second conductivity-type semiconductor layer.

4. The semiconductor light emitting device of claim 1, wherein the electrode pad covers the entire surface of the reflective metal layer such that the reflective metal layer is not exposed to the outside.

5. The semiconductor light emitting device of claim 1, wherein the reflective metal layer fills the open region.

6. The semiconductor light emitting device of claim 5, wherein the insulating layer covers a surface of the light-transmissive conductive layer exposed from an inner side of the open region.

7. The semiconductor light emitting device of claim 1, further comprising:
a current interrupting layer interposed between the reflective metal layer and the second conductivity-type semiconductor layer.

8. The semiconductor light emitting device of claim 7, wherein the current interrupting layer is disposed on a region corresponding to an electrode pad formation region.

9. The semiconductor light emitting device of claim 7, wherein the current interrupting layer comprises an undoped semiconductor or an insulating material.

10. The semiconductor light emitting device of claim 1, wherein the reflective metal layer and the electrode pad include the same metal.

11. The semiconductor light emitting device of claim 1, wherein the reflective metal layer includes at least one of silver (Ag), nickel (Ni), aluminum (Al), rhodium (Rh), ruthenium (Ru), palladium (Pd), iridium (Ir), magnesium (Mg), zinc (Zn), platinum (Pt), or gold (Au).

12. The semiconductor light emitting device of claim 1, wherein the electrode pad comprises any one of Ni/Au, Ag/Au, Ti/Au, Ti/Al, Cr/Au, Pd, and Au.

13. The semiconductor light emitting device of claim 1, wherein a surface of the light emitting structure on which the second electrode is disposed is a main light emission surface of the semiconductor light emitting device.

14. The semiconductor light emitting device of claim 1, wherein the insulating layer covers the entire open region.

15. The semiconductor light emitting device of claim 1, wherein the insulating layer covers a portion of the open region.

16. A semiconductor light emitting device comprising:
a light emitting structure disposed on a substrate, the light emitting structure including:
a first conductivity-type semiconductor layer,
an active layer, and
a second conductivity-type semiconductor layer;
a first electrode electrically connected to the first conductivity-type semiconductor layer;
a light-transmissive conductive layer disposed on the second conductivity-type semiconductor layer; and
a second electrode disposed on the light-transmissive conductive layer, the second electrode including:
a reflective metal layer including a portion disposed on the second conductivity-type semiconductor layer, and
an insulating layer interposed between the light-transmissive conductive layer and the reflective metal layer.

17. The semiconductor device of claim 16, wherein the second electrode further comprises:
an electrode pad disposed on the reflective metal layer, and
a branch electrode extending from the electrode pad so as to be in contact with the light-transmissive conductive layer.

18. The semiconductor device of claim 16, wherein the first conductivity-type semiconductor layer has n-type conductivity and the second conductivity-type semiconductor layer has p-type conductivity.

19. The semiconductor device of claim 16, wherein the insulating layer extends from a lateral surface of the reflective metal layer to be interposed between the second conductivity-type semiconductor layer and the reflective metal layer.

20. The semiconductor device of claim 19, wherein the electrode pad covers the entire surface of the reflective metal layer such that the reflective metal layer is not exposed to the outside.

21. The semiconductor device of claim 16, further comprising:
a current interrupting layer interposed between the second conductivity-type semiconductor layer and at least the portion of the reflective metal layer

22. The semiconductor device of claim 16, wherein the current interrupting layer is disposed on a region corresponding to an electrode pad formation region.

23. The semiconductor device of claim 16, wherein the first and second conductivity layers comprise AlₓIn_{y}Ga(_{1-x-y})N (0≦x≦1, 0≦y≦1, 0≦x+y≦1).

24. The semiconductor device of claim 16, wherein the light-transmissive conductive layer comprises a metal oxide.
